(19) United States
(12) Patent Application Publication
(10) Pub. No.: US 2014/0112079 A1
(43) Pub. Date: Apr. 24, 2014

(54) CONTROLLING AND STAGGERING OPERATIONS TO LIMIT CURRENT SPIKES

(71) Applicant: Apple Inc., Cupertino, CA (US)

(72) Inventors: Nir J. Wakrat, Los Altos, CA (US); Daniel J. Post, Campbell, CA (US); Kenneth L. Herman, San Jose, CA (US); Vadim Khmelnitsky, Foster City, CA (US); Nicholas C. Seroff, Los Gatos, CA (US); Hsiao H. Thio, San Jose, CA (US); Matthew J. Byom, Campbell, CA (US)

(73) Assignee: Apple Inc., Cupertino, CA (US)

(21) Appl. No.: 14/144,041

(22) Filed: Dec. 30, 2013

Related U.S. Application Data
(62) Division of application No. 12/843,419, filed on Jul. 26, 2010.
(60) Provisional application No. 61/294,060, filed on Jan. 11, 2010.

(51) Int. Cl. G11C 16/30

(52) U.S. Cl. CPC G11C 16/30
USPC 365/185.18

(57) ABSTRACT

Systems and methods are disclosed for managing the peak power consumption of a system, such as a non-volatile memory system (e.g., flash memory system). The system can include multiple subsystems and a controller for controlling the subsystems. Each subsystem may have a current profile that is peaky. Thus, the controller may control the peak power of the system by, for example, limiting the number of subsystems that can perform power-intensive operations at the same time or by aiding a subsystem in determining the peak power that the subsystem may consume at any given time.

### CROSS-REFERENCE TO RELATED APPLICATIONS

This application claims the benefit of U.S. Provisional Patent Application No. 61/294,060, filed on Jan. 11, 2010, which is hereby incorporated by reference herein in its entirety.

### FIELD OF THE INVENTION

This can relate to managing the peak power consumption of a system, such as a NAND flash memory system.

### BACKGROUND OF THE DISCLOSURE

Electronic systems are becoming more and more complex and are incorporating more and more components. As such, peak power issues for these systems continue to be a concern. In particular, because many of the components in a system may operate at the same time, the system can suffer from power or current spikes. This effect may be particularly pronounced when the system components are each performing high-power operations.

A flash memory system, which is commonly used for mass storage in consumer electronics, is one example of a current system in which peak power issues are a concern.

### SUMMARY OF THE DISCLOSURE

Systems and methods are disclosed for managing the peak power consumption of a system, such as flash memory system (e.g., NAND flash memory system).

A system may be provided that includes multiple subsystems and a controller for controlling the subsystems. Each of the subsystems may have substantially the same features and functionality and may have a current profile that is peaky. In particular, each subsystem may perform operations that vary in power consumption so, over time, there may be current peaks in a subsystem's current profile corresponding to the more high-power operations.

In some embodiments, the system may be or include a memory system. An example of a memory system that may have particularly peaky current profiles is a flash memory system (e.g., NAND flash memory system). In such flash systems, the subsystems may include different flash dies, which may perform power-intensive operations that cause spikes in the flash die current consumption profile. The controller that controls the flash dies may include a host processor (e.g., in a raw or managed NAND system) and/or a flash controller (e.g., in a managed NAND system). In other embodiments, instead of a flash memory system, the system can include any other suitable non-volatile memory system, such as a hard drive system, or any suitable parallel-computing system.

The controller (e.g., the host processor and/or the flash controller) may be configured to manage the peak power consumption of the system. For example, the controller may limit the number of subsystems that can perform power-intensive operations at the same time or aid a subsystem in determining the peak power the subsystem may consume at any given time. This way, the total power of the system may be maintained within a threshold level suitable for operation of the hosting system.

In some embodiments, a time division multiplexing scheme may be used, where the controller assigns each subsystem a time slot for performing power-intensive operations. In other embodiments, the controller may be configured to grant permission to at most a predetermined number of subsystems at any given time to perform power-intensive operations. Alternatively, the controller may keep track of the sum of the expected current usage of those subsystems performing substantial operations, and may grant permission to additional subsystems based on the sum. In still other embodiments, the controller may provide power status information about the system (e.g., the total number of subsystems performing power-intensive operations) to a particular subsystem to indicate to the particular subsystem what types of operations may be appropriate to perform.

### BRIEF DESCRIPTION OF THE DRAWINGS

The above and other aspects and advantages of the invention will become more apparent upon consideration of the following detailed description, taken in conjunction with accompanying drawings, in which like reference characters refer to like parts throughout, and in which:

FIG. 1 is a schematic view of an illustrative system including a controller and multiple subsystems configured in accordance with various embodiments of the invention;

FIG. 2A is a schematic view of an illustrative non-volatile memory system including a host processor and a managed non-volatile memory package configured in accordance with various embodiments of the invention;

FIG. 2B is a schematic view of an illustrative non-volatile memory system including a host processor and a raw non-volatile memory package configured in accordance with various embodiments of the invention;

FIG. 2C is a graph illustrating a peaky current consumption profile of a memory subsystem in accordance with various embodiments of the invention;

FIG. 3 is a flowchart of an illustrative process for staggering power-intensive operations of different subsystems using a time division multiplexing scheme in accordance with various embodiments of the invention;

FIG. 4 is a flowchart of an illustrative process for managing power-intensive operations of different subsystems using requests by a subsystem in accordance with various embodiments of the invention; and

FIG. 5 is a flowchart of an illustrative process for managing power-intensive operations of different subsystems by providing, to a subsystem, power status information of the system in accordance with various embodiments of the invention.

### DETAILED DESCRIPTION OF THE DISCLOSURE

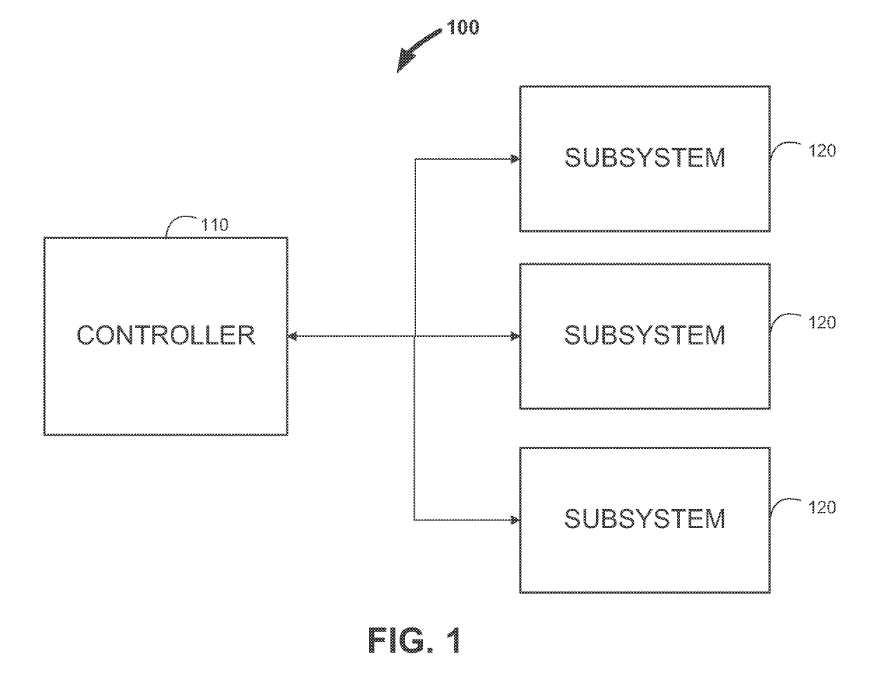

FIG. 1 is a schematic view of illustrative system 100 that may suffer from peak power issues. In particular, system 100 can include controller 110 and multiple subsystems 120, where the combined power consumption of subsystems 120 may be undesirably peaky when not suitably managed by controller 110. In some embodiments, each of subsystems 120 may have substantially the same features and functionalities. For example, subsystems 120 may have been manufactured using substantially the same manufacturing process or may have substantially the same specifications (e.g., in terms of materials used, etc.).

Each of subsystems 120 may have a current or power profile that is peaky. In particular, during operation, each of subsystems 120 may perform some operations that are higher in power and some operations that are lower in power. Thus, over time, the current or power profile of each of subsystems 120 may rise and fall, where the highest peaks occur when a subsystem is performing its most high-power operation. If multiple subsystems perform high-power operations at the same time, the overall power or current profile for system 100 may reach a peak power level that is above the power threshold or specification for system 100. As used herein, a “power-intensive operation” may be a subsystem operation that may have a substantial effect on the overall power levels of the system. For example, a “power-intensive operation” may refer to an operation that requires or is expected to consume at least a predetermined amount of current.

Controller 110 may be configured to control, manage, and/or synchronize the operations performed by subsystems 120 so that such overall system peaks do not (or are less likely) to occur. In particular, as described in greater detail below, controller 110 may control subsystems 120 such that at most a predetermined number of subsystems 120 are performing power-intensive operations at the same time or by aiding a subsystem in determining the peak power the subsystem may use at any given time. Controller 110 may include any suitable combination of hardware-based (e.g., application-specific integrated circuits, field programmable arrays, etc.) and software-based components (e.g., processors, microprocessors, etc.) for managing subsystems 120.

System 100 is illustrated as having three subsystems, but it should be understood that system 100 can include any suitable number of subsystems (e.g., two, four, five, or more subsystems).

System 100 may be any suitable type of electronic system that could suffer from peak power issues. For example, system 100 may be or include a parallel-computing system or a memory system (e.g., a hard drive system or a flash memory system, such as a NAND flash memory system, etc.).

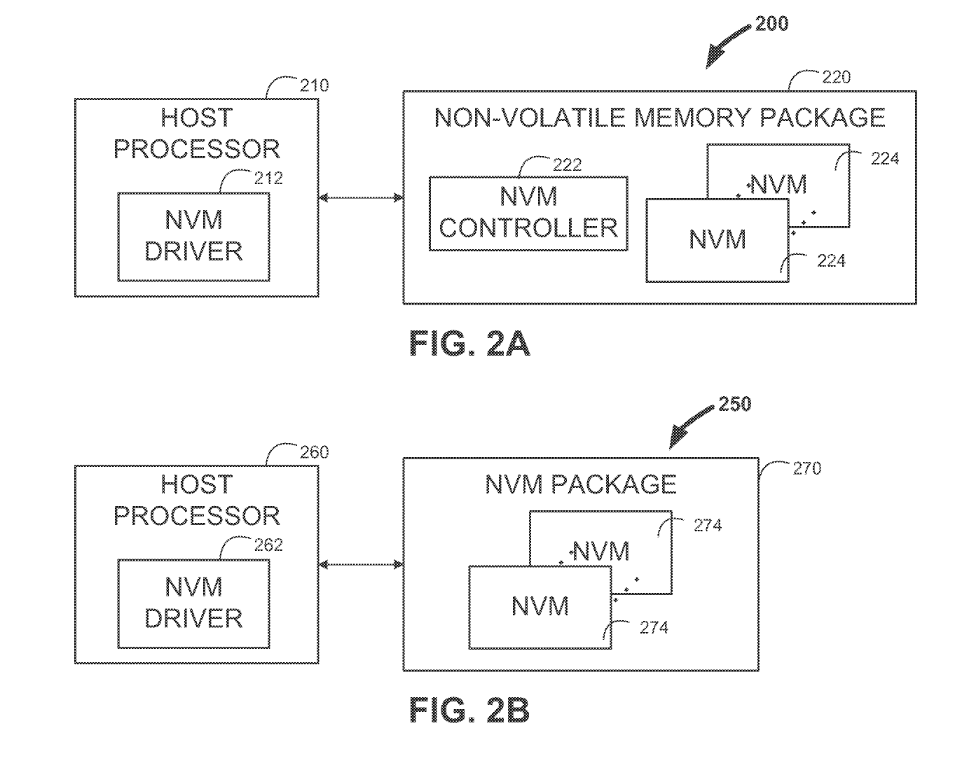

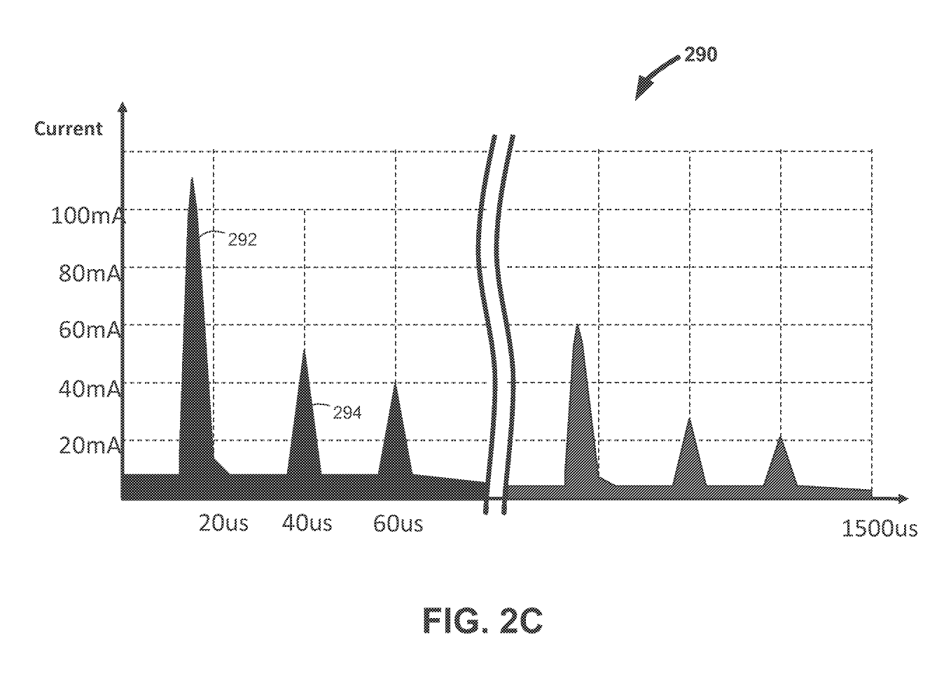

FIGS. 2A and 2B are schematic views of memory systems, which are examples of various embodiments of system 100 of FIG. 1. Looking first to FIG. 2A, memory system 200 can include host processor 210 and at least one non-volatile memory (“NVM”) package 220. Host processor 210 and optionally NVM package 220 can be implemented in any suitable host device or system, such as a portable media player (e.g., an iPod™ made available by Apple Inc. of Cupertino, Calif.), a cellular telephone (e.g., an iPhone™ made available by Apple Inc.), a pocket-sized personal computer, a personal digital assistance (“PDA”), a desktop computer, or a laptop computer.

Host processor 210 can include one or more processors or microprocessors that are currently available or will be developed in the future. Alternatively or in addition, host processor 210 can include or operate in conjunction with any other components or circuitry capable of controlling various operations of memory system 200 (e.g., application-specific integrated circuits (“ASICs”)). In a processor-based implementation, host processor 210 can execute firmware and software programs loaded into a memory (not shown) implemented on the host. The memory can include any suitable type of volatile memory (e.g., cache memory or random access memory (“RAM”), such as double data rate (“DDR”) RAM or static RAM (“SRAM”)). Host processor 210 can execute NVM driver 212, which may provide vendor-specific and/or technology-specific instructions that enable host processor 210 to perform various memory management and access functions for non-volatile memory package 220.

NVM package 220 may be a ball grid array (“BGA”) package or other suitable type of integrated circuit (“IC”) package. NVM package 220 may be managed NVM package. In particular, NVM package 220 can include NVM controller 222 coupled to any suitable number of NVM dies 224. NVM controller 222 may include any suitable combination of processors, microprocessors, or hardware-based components (e.g., ASICs), and may include the same components as or different components from host processor 210. NVM controller 222 may share the responsibility of managing and/or accessing the physical memory locations of NVM dies 224 with NVM driver 212. Alternatively, NVM controller 222 may perform substantially all of the management and access functions for NVM dies 224. Thus, a “managed NVM” may refer to a memory device or package that includes a controller (e.g., NVM controller 222) configured to perform at least one memory management function for a non-volatile memory (e.g., NVM dies 224). One of the management functions that can be performed by NVM controller 222 may be to control the peak power consumption of memory system 200. This way, NVM controller 222 may manage the power consumption of NVM package 210 (and NVM dies 224 in particular) without affecting the actions or performance of host processor 210.

Other memory management and access functions that may be performed by NVM controller 222 and/or host processor 210 for NVM dies 224 can include issuing read, write, or erase instructions and performing wear leveling, bad block management, garbage collection, logical-to-physical address mapping, SLC or MLC programming decisions, applying error correction or detection, and data queuing to set up program operations.

NVM dies 224 may be used to store information that needs to be retained when memory system 200 is powered down. As used herein, and depending on context, a “non-volatile memory” can refer to NVM dies in which data can be stored, or may refer to a NVM package that includes the NVM dies. NVM dies 224 can include NAND flash memory based on floating gate or charge trapping technology, NOR flash memory, erasable programmable read only memory (“EPROM”), electrically erasable programmable read only memory (“EEPROM”), ferroelectric RAM (“FRAM”), magnetoresistive RAM (“MRAM”), phase change memory (“PCM”), any other known or future types of non-volatile memory technology, or any combination thereof.

Referring now to FIG. 2B, a schematic view of memory system 250 is shown, which may be an example of another embodiment of system 100 of FIG. 1. Memory system 250 may have any of the features and functionalities described above in connection with memory system 200 of FIG. 2A. In particular, any of the components depicted in FIG. 2B may have any of the features and functionalities of like-named components in FIG. 2A, and vice versa.

Memory system 250 can include host processor 260 and non-volatile memory package 270. Unlike memory system 200 of FIG. 2A, NVM package 270 does not include an embedded NVM controller, and therefore NVM dies 274 may be managed entirely by host processor 260 (e.g., via NVM driver 262). Thus, non-volatile memory package 270 may be referred to as a “raw NVM.” A “raw NVM” may refer to a memory device or package that may be managed entirely by a host controller or processor (e.g., host processor 260) implemented external to the NVM package. One of the management functions performed by host processor 260 in such raw NVM implementations may be to control the peak power consumption of memory system 250. Host processor 260 may also perform any of the other memory management and access functions discussed above in connection with host processor 210 and NVM controller 222 of FIG. 2A.

With continued reference to both FIGS. 2A and 2B, NVM controller 222 (FIG. 2A) and host processor 270 (e.g., via NVM driver 262) (FIG. 2B) may each embody the features and functionality of controller 110 discussed above in connection with FIG. 1, and NVM dies 224 and 274 may embody the features and functionality of subsystems 120 discussed above in connection with FIG. 1. In particular, NVM dies 224 and 274 may each have a peaky current profile, where the highest peaks occur when a die is performing its most power-intensive operations. In flash memory embodiments, an example of such a power-intensive operation is a sensing operation (e.g., current sensing operation), which may be used when reading data stored in memory cells. Such sensing operations may be performed, for example, responsive to read requests from a host processor and/or a NVM controller when verifying that data was properly stored after programming.

FIG. 2C shows illustrative current consumption profile 290. Current consumption profile 290 gives an example of the current consumption of a NVM die (e.g., one of NVM dies 224 or 274) during a verification-type sensing operation. With several peaks, including peaks 292 and 294, current consumption profile 290 illustrates how peaky a verification-type sensing operation may be. These verification-type sensing operations may be of particular concern, as these operations may be likely to occur across multiple NVM dies at the same time (i.e., due to employing parallel writes across multiple dies). Thus, if not managed by NVM controller 222 (FIG. 2A) or host processor 260, the peaks of different NVM dies may overlap and the total current sum may be unacceptably high. This situation may occur with other types of power-intensive operations, such as erase and program operations.

Thus, as discussed above, the memory management and access functions performed by NVM controller 222 (FIG. 2A) or host processor 260 (FIG. 2B) can further include controlling NVM dies 224 or 274 to manage the overall peak power of their respective systems by, for example, limiting the number of NVM dies 224 or 274 that may perform power-intensive operations at the same time (e.g., staggering power-intensive operations so that current peaks are unlikely to occur at the same time) or by aiding a NVM die in determining the peak power that it may consume at any given time. This way, NVM controller 222 (FIG. 2A) or host processor 260 (FIG. 2B) may prevent the overall peak power consumption of their respective memory systems from being too high.

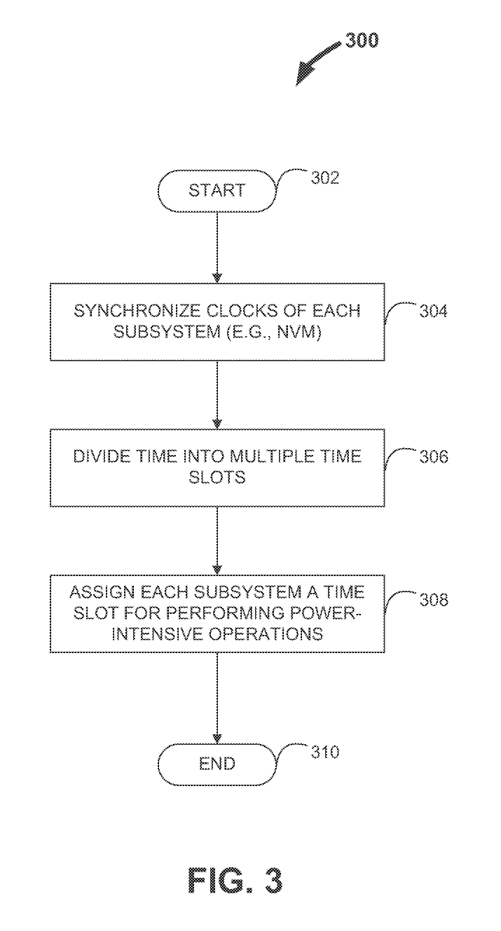

Returning to FIG. 1, but with continued reference to FIGS. 2A and 2B, controller 110 (e.g., NVM controller 222 (FIG. 2A) or host processor 260 (FIG. 2B)) may use any suitable approach to manage the overall peak power consumption of system 100. In some embodiments, a time division multiplexing scheme may be used, where controller 110 assigns each subsystem a time slot for performing power-intensive operations. This may enable subsystems 120 to stagger their power-intensive operations. One example of this approach will be described below in connection with FIG. 3.

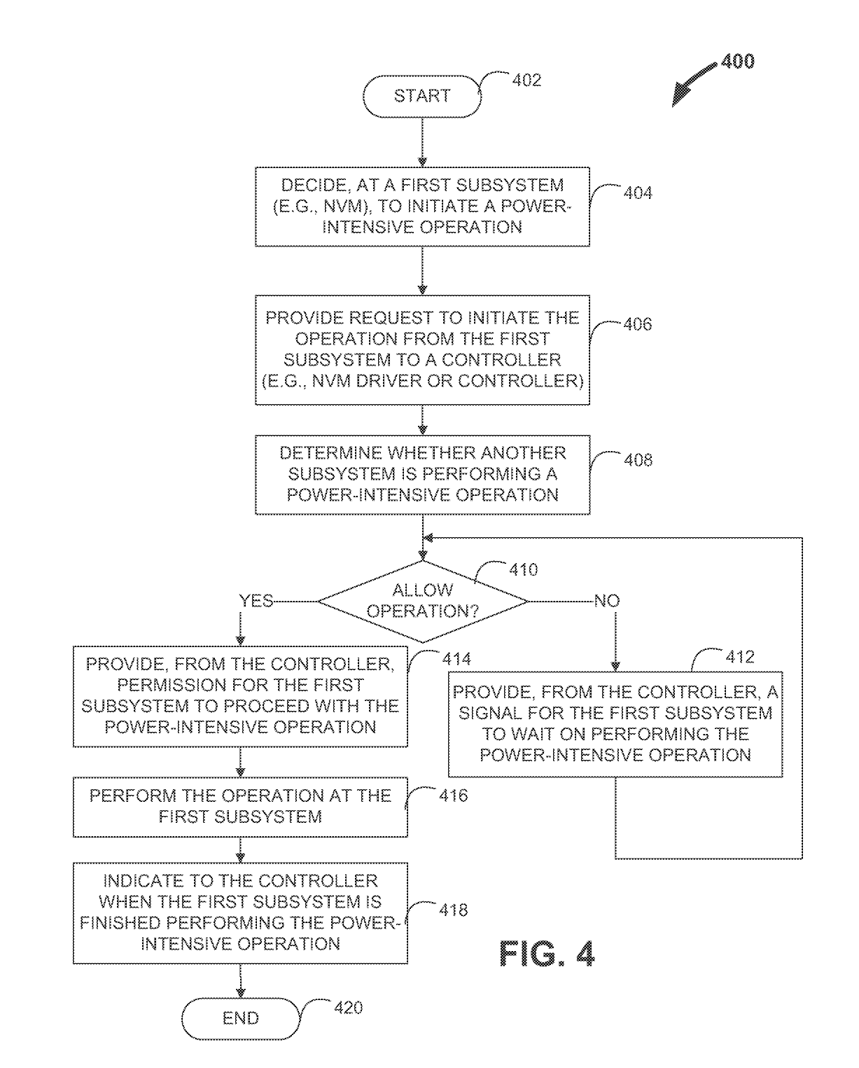

In other embodiments, controller 110 may be configured to grant permission to at most a predetermined number of subsystems at any given time to perform power-intensive operations. For example, subsystems 120 may each request permission from controller before performing a power-intensive operation, and controller 110 may manage the number of subsystems 120 that are granted permission. Whether controller 110 grants permission to a subsystem may depend, for example, on the expected total current consumption of the subsystems that have already been granted permission. One example of this approach will be described below in connection with FIG. 4.

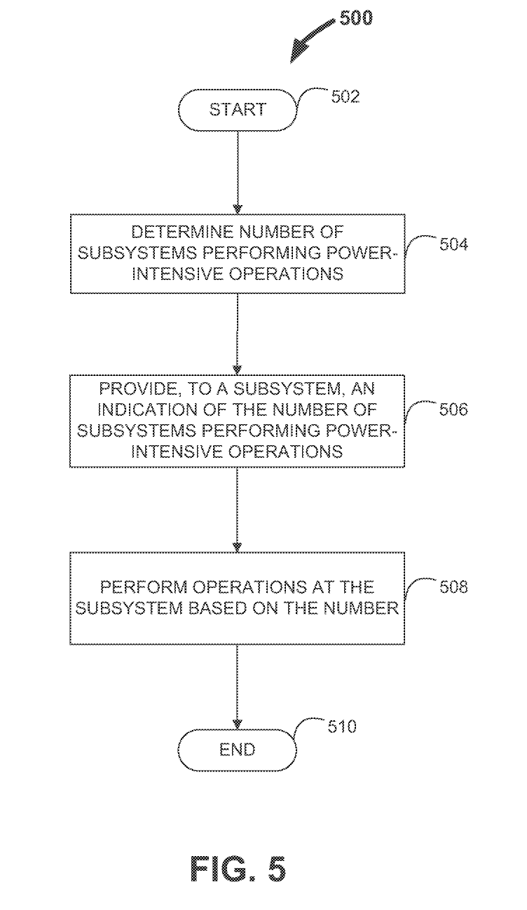

In still other embodiments, controller 110 may provide power status information about the system to a particular subsystem to indicate to the particular subsystem what types of operations may be appropriate to perform. For example, the power status information may indicate the total number of subsystems 110 currently performing power-intensive operations, or the power status information may indicate the expected current sum utilized by those subsystems 110 performing power-intensive operations. An example of this approach will be described below in connection with FIG. 5. It should be understood that these three approaches are merely illustrative and that other approaches may be implemented by controller 110 instead.

FIGS. 3-5 are flowcharts of illustrative processes that may be performed by systems configured in accordance with various embodiments of the invention. For example, any of the systems discussed above in connection with FIGS. 1, 2A, and 2B (e.g., a flash memory system, a parallel-computing system, etc.) may be configured to perform the steps of one or more of these processes.

Turning first to FIG. 3, a flowchart of illustrative process 300 is shown for timing power-intensive operations amongst multiple subsystems using a time division multiplexing scheme. Process 300 may begin at step 302. Then, at step 304, the clocks of each subsystem may be synchronized. The clocks may be synchronized using any suitable approach, such as feeding the same clock (i.e., clock signals derived from the same source clock) to each of the subsystems or using a controller to synchronize each subsystem's internal clock.

Then, at step 306, time may be divided into multiple time slots. The number of time slots may be based on the number of subsystems, such as providing one time slot per subsystem, one time slot per two subsystems, etc. The time slots may be of any suitable length, such as N clock cycles in length, where N can be any suitable positive integer. For example, if there are four subsystems, step 306 may involve creating and rotating between four time slots of N clock cycles each.

Continuing to step 308, each subsystem may be assigned to one of the time slots. During the time slot assigned to a particular subsystem, the subsystem may perform any power-intensive operations, such as program operations in flash memory systems. During a time slot not assigned to a particular subsystem, the subsystem may hold off on performing power-intensive operations, and may instead stall until its assigned time slot begins and/or perform non-power-intensive operations in the meantime. In some embodiments, each subsystem may be assigned to a different one of the time slots so that only one subsystem may perform power-intensive operations at any given time. In other embodiments, more than one (but less than all) of the subsystems may be assigned to the same time slot. By using this time division multiplexing scheme, the peak power may be limited, as this scheme may ensure that power-intensive operations are staggered.

Process 300 may continue to step 310 and end. In other embodiments, process 300 may return to step 302 after a suitable amount of time in embodiments where the subsystems' clocks may need to be periodically adjusted to remain in synchronization.

Turning now to FIG. 4, a flowchart of an illustrative process is shown for synchronizing power-intensive operations amongst multiple subsystems using requests to a controller. Process 400 may begin at step 402. Then, at step 404, one of the subsystems in the system (referred to as the first subsystem in FIG. 4) may decide to initiate a power-intensive operation. For example, in a flash memory system, the next queued operation for one of the flash dies may be a power-intensive operation, such as a sensing operation to read data (e.g., within a read-verify operation).

At step 406, the subsystem may provide a request to the controller of the system (e.g., a NVM driver or controller for non-volatile memory systems) to initiate the power-intensive operation. For example, the subsystem may request permission from the controller to perform the power-intensive operation via a physical communications link dedicated to this purpose, by issuing an appropriate command via a suitable communications protocol or interface, or using any other suitable approach.

The controller may then, at step 408, determine whether one or more other subsystems are performing power-intensive operations. In some embodiments, the controller may make this determination by verifying whether the controller has already granted permission to perform a power-intensive operation to more than a predetermined number (e.g., one, two, etc.) of other subsystems and that these operations are not yet complete. At step 410, the controller may decide whether to allow the subsystem to perform the power-intensive operation. In some embodiments, the controller may not allow the operation if a predetermined number of other systems are currently performing power-intensive operations, and may allow the operation otherwise.

In some embodiments, the determination at step 408 may further include determining the expected combined peak current of the one or more other subsystems performing power-intensive operations. This way, at step 410, instead of allowing (or not allowing) an operation to proceed based on the number of other subsystems performing power-intensive operations, the controller can make this determination based on expected current usage. The controller may, for example, decide to allow an operation if there are several subsystems performing less power-consuming power-intensive operations, but may decide not to allow the operation if there are fewer subsystems (e.g., one other subsystem) performing more power-consuming power-intensive operations.

If, at step 410, the controller determines that the operation should not be allowed, process 400 may move to step 412, and a signal may be provided, from the controller to the subsystem, to wait on performing the power-intensive operation. The signal may be given in any suitable form, such as a signal on a dedicated physical line, as an appropriate command using a suitable protocol or interface, etc. This way, the subsystem can be instructed to hold off on performing the operation, and may instead stall further operations or perform other non-power-intensive operations in the meantime. This may ensure that not too many subsystems are performing power-intensive operations at the same time, or that the peak current of the overall system does not increase beyond a certain point. Process 400 may then return to step 410 to again determine whether the power-intensive operation can be allowed by the controller (e.g., whether one or more subsystems have finished performing power-intensive operations).

If, at step 410, the controller determines that the power-intensive operation should be allowed, process 400 may move to step 414. At step 414, permission may be provided, from the controller to the subsystem, to proceed with the power-intensive operation. The permission may be provided, for example, as a signal on a dedicated physical line, as an appropriate command using a suitable protocol or interface, or using any other suitable approach. Then, at step 416, the power-intensive operation may be performed by the subsystem. When the subsystem is finished performing the power-intensive operation, the subsystem may indicate the completion of the power-intensive operation to the controller at step 418. The indication may be an express indication to the controller or the controller can infer the completion of the power-intensive operation when the subsystem provides a result of the operation (e.g., for a flash memory system, any resulting data from a read operation). This way, the controller may be able to grant permission to another subsystem to perform a power-intensive operation.

Process 400 may then end at step 420.

Turning now to FIG. 5, a flowchart of illustrative process 500 is shown for managing power-intensive operations amongst multiple subsystems (e.g., flash dies) by providing, to a subsystem, power status information of the system. Process 500 may begin at step 502. At step 504, the number of subsystems performing power-intensive operations may be determined by, for example, a controller that can control the subsystems. For example, using any of the techniques discussed above, the subsystems may each be configured to signal to the controller when the subsystem begins or ends a power-intensive operation. This way, the controller can keep track of the number of subsystems performing power-intensive operations at any given time.

Then, at step 506, an indication of the number of subsystems performing power-intensive operations may be provided from the controller to one or more of the subsystems. The indication may be provided to all of the subsystems in the system or to all of the subsystems performing power-intensive operations. The indication may be provided at any suitable time or responsive to any suitable stimulus, such as in response to receiving an indication from a subsystem that the subsystem is about to begin performing a power-intensive operation. This way, when the subsystem sets up the power-intensive operation, the subsystem may be informed of how many other subsystems are also performing power-intensive operations.

Process 500 may then continue to step 506. At step 506, operations may be performed at the subsystem based on the number of subsystems performing power-intensive operations. Often, when performing an operation, a subsystem may trade off speed and power (i.e., the subsystem may perform the operation at high speed at the cost of increasing power consumption, or the subsystem may perform the operation at low power at the cost of the operation taking a longer time to complete). For example, a subsystem can increase speed at the cost of power by parallelizing computations instead of serializing them, or by charging a charge pump at a higher rate. Thus, if at step 506, the subsystem receives an indication that it is the only subsystem performing a power-intensive operation, the subsystem may use a higher/highest-speed, higher/highest-power scheme. The greater the number of subsystems performing power-intensive operations, the less power a particular subsystem may decide to use. Even if a subsystem decides to use a slower, lower power scheme, the overall speed of the system may be improved, as more subsystems may be able to operate at the same time than would otherwise be possible had each subsystem operated in a higher-power mode.

Process 500 may then end at step 510.

It should be understood that processes 300, 400, and 500 of FIGS. 3-5 are merely illustrative. Any of the steps may be removed, modified, or combined, and any additional steps may be added, without departing from the scope of the invention.

The described embodiments of the invention are presented for the purpose of illustration and not of limitation.

1. A non-volatile memory system, comprising:
a plurality of memory dies; and
a controller configured to permit at most a number of the dies to perform operations at substantially the same time.

2. The non-volatile memory system of claim 1, wherein the operations comprise sensing operations.

3. (canceled)

4. (canceled)

5. A method of managing peak power consumption in a non-volatile memory system, the non-volatile memory system comprising a plurality of memory subsystems, the method comprising:
synchronizing clocks of each of the memory subsystems; and
assigning each of the memory subsystems a time slot for performing operations.

6. The method of claim 5, wherein the synchronizing comprises feeding each of the memory systems a clock signal derived from the same clock source.

7. The method of claim 5, wherein each of the memory subsystems comprises an internal clock, and wherein the synchronizing comprises synchronizing the internal clock of each of the memory subsystems.

8. The method of claim 5, wherein the time slots are based on the number of memory subsystems, and wherein the time slots continuously repeat.

9. The method of claim 5, further comprising:
deciding, at one of the memory subsystems, to perform an operation;
determining whether the one of the memory subsystems is assigned to a current time slot; and
performing the operation based on whether the one of the memory subsystems is assigned to the current time slot.

10.-21. (canceled)

22. The non-volatile memory system of claim 1, wherein the controller is further configured to:
receive an indication of available power; and
adjust the number based on the received indication.

23. The non-volatile memory system of claim 1, wherein the controller is further configured to:
adjust the number based on an expected current usage of at least one operation.

24. The non-volatile memory system of claim 1, wherein the controller is further configured to:
adjust the number based on a type of operation being performed.

25. The non-volatile memory system of claim 1, wherein the operation is a program operation.

26. The non-volatile memory system of claim 1, wherein the operation is a read operation.

27. The non-volatile memory system of claim 1, wherein the operation is an erase operation.

28. The non-volatile memory system of claim 1, wherein the operation is a power intensive operation that can affect availability of power for a system other than the non-volatile memory system.

29. The non-volatile memory system of claim 5, wherein the operation is a program operation.

30. The non-volatile memory system of claim 5, wherein the operation is a read operation.

31. The non-volatile memory system of claim 5, wherein the operation is an erase operation.

32. The non-volatile memory system of claim 5, wherein the operation is a power intensive operation that can affect availability of power for a system other than the non-volatile memory system.

33. A memory system, comprising:
a plurality of non-volatile memory (“NVM”) dies, each of the dies independently operable to perform an operation; and
a controller coupled to the plurality of memory dies, wherein the controller staggers operations performed by at least two of the plurality of dies to limit the overlap of current peaks associated with the operations.

34. The memory system of claim 33, wherein the controller is further configured to stagger the operations so that they do not exceed a power threshold

35. The memory system of claim 34, wherein the power threshold is received from an external source

36. The memory system of claim 33, wherein the controller is further configured to limit concurrent operations of the NVM dies.

37. The memory system of claim 33, wherein the controller is further configured to prevent concurrent execution of a first operation on a first NVM die with a second operation on a second NVM die if the concurrent execution would cause the system to exceed a power threshold.

38. The memory system of claim 33, wherein the controller is further configured to stagger the operations so that a cumulative power of a system does not exceed a threshold.

39. The memory system of claim 33, wherein the controller is further configured to selectively adjust staggering of operations performed by at least two of the plurality of dies.

40. The memory system of claim 33, wherein the controller is further configured to selectively adjust staggering of operations performed by at least two of the plurality of dies based on a type of operations being performed.

41. The memory system of claim 40, wherein when the type of operation requires relatively less power intensive operation, the operations are staggered to permit relatively more concurrent operations.

42. The memory of claim 40, wherein when the type of operation requires relatively more power intensive operations, the operations are staggered to permit relatively fewer concurrent operations.
